(19) United States
(12) Patent Application Publication
(10) Pub. No.: US 2005/0133829 A1
(43) Pub. Date: Jun. 23, 2005

(54) High-frequency semiconductor device

(75) Inventors: Tetsuo Kunii, Tokyo (JP); Yoshitaka Kamo, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Denki Kabushiki Kaisha, Tokyo (JP)

(21) Appl. No.: 10/995,133

(22) Filed: Nov. 24, 2004

(30) Foreign Application Priority Data
Dec. 22, 2003 (JP) 2003-424335

(51) Int. Cl. H01L 21/338; H01L 29/80

(52) U.S. Cl. 257/280; 438/167; 257/281; 438/570

(57) ABSTRACT

A high-frequency semiconductor device includes: a first cell which includes of gate electrodes on a surface of an epitaxial layer of a substrate, drain electrodes and source electrodes alternately located relative to the gate electrodes, a source electrode connection wiring striding over the gate electrodes and the drain electrodes and connecting the source electrodes, and a drain electrode connection wiring striding over the gate electrodes and the source electrodes and connecting the drain electrodes; a second cell which has the same configurations as the first cell, is located in an extended direction of each of the gate electrodes of the first cell, and has the drain electrode connection wiring proximate to the drain electrode connection wiring of the first cell; and a gate electrode bar located between the drain electrode connection wirings of the first and second cells, and to which the gate electrodes of the first and second cells are connected.

### BACKGROUND OF THE INVENTION

1. Field of the Invention

The present invention relates to a high-frequency semiconductor device. More specifically, the present invention relates to a high-frequency semiconductor device for use in a communication apparatus such as a transmitter-receiver for satellite communication or mobile communication.

2. Description of the Related Art

Following a rapid increase in communication demand, a capacity of a communication system has been intended to be increased. To do so, it is necessary to improve a high speed performance, reduce a size, improve efficiency, cut down a cost of a communication apparatus.

For a microwave device used in the communication apparatus such as a transmitter/receiver for satellite communication or mobile communication which uses high frequencies, metal semiconductor field effect transistors (MESFET's), for example, are employed as transistors having good high frequency characteristics.

If a high-frequency amplifier is to be constituted using the high-frequency MESFET's with sources grounded, a device which uses chips each having a large gate width is required so as to obtain high power output.

A high-frequency MESFET chip is constituted so that drain electrodes, gate electrodes, and source electrodes are alternately arranged to extend in a gate width direction in an operating region provided on a surface of a semiconductor substrate, and so that a plurality of unit MESFET's, each composed by one drain electrode, one gate electrode, and one source electrode, are arranged in parallel in a direction orthogonal to an extension direction of the respective electrodes. In a direction in which the unit MESFET's are arranged in parallel in the operating region, a plurality of gate pads are provided on one side of the semiconductor substrate to put the unit MESFET's therebetween, a plurality of drain pads are arranged in parallel on the other side, and a plurality of source pads are arranged so that each source pad is put between the two gate pads.

A metal plated layer is provided, as a heat sink, on a rear surface of the semiconductor substrate. To ground sources, the source pads are connected to the metal plated layer through via holes.

If this high frequency MESFET chip is to be assembled in a package, then the high frequency MESFET chip is bonded to a package by die-bonding using an AuSn solder or the like, and temporarily connected to leads of the package through a matching circuit or the like provided on the substrate from the gate pads and the drain pads, and a DC line and an RF signal line are formed.

In order for a semiconductor device which employs the high-frequency MESFET chips to realize improved high power output, it is necessary to (i) enlarge the gate width of each of the unit MESFET's that constitute the high-frequency MESFET, and (ii) increase the number of the unit MESFET's that constitute the high-frequency MESFET.

However, if the gate width of the unit MESFET is simply increased so as to satisfy the requirement (i) above, a gate resistance may possibly be increased and a reduction in gain may possibly occur.

Further, if the number of unit MESFET's is increased so as to satisfy the requirement (ii) above, a size of the high-frequency MESFET chip in a lateral direction which is a direction in which the unit MESFET's are arranged in parallel is increased. If the lateral size of the chip is increased, the following disadvantages occur. When the MESFET chip is bonded to the package by die-bonding using the AuSn solder or the like during assembly of the device, warping of the MESFET chip occurs due to a difference in coefficient of thermal expansion between the semiconductor substrate and the metal plated layer that serves as the heat sink. As a result, a thickness of the solder is increased near both ends of the MESFET chip, thereby greatly increasing a thermal resistance value of the device. Besides, because of the increased size of the package, a cost is increased.

To prevent these disadvantages, a plurality of unit transistors are arranged in two rows within one chip so that the rows face each other, thereby suppressing an increase in the lateral dimensions of the chip.

As a conventional high-frequency MESFET chip structure, there is known, for example, a structure in which a plurality of unit transistors are arranged in two rows within one chip so that the rows face each other, and in which a gate pad for inputting a signal which enables the unit transistors in two rows to operate with the same signal is arranged between the unit transistors in two rows (see, for example, Japanese Patent Application Laid-Open No. 2-114561, page 2, upper left column, and FIGS. 1 and 2).

As another conventional high-frequency MESFET chip structure, there is known a structure in which a plurality of gate electrodes, drain electrodes, and source electrodes are formed around a gate pad and a drain pad on their both sides in a linearly symmetric manner, and in which two source pads are provided around the electrodes (see, for example, Japanese Patent Application Laid-Open No. 4-252036, paragraph [0025], and FIGS. 1 and 4).

As yet another conventional high-frequency MESFET chip structure, there is known the following structure. Two rectangular active regions extending laterally in a space are arranged in parallel, whereby respective unit transistors arranged in parallel in each active region are arranged vertically in two rows in a longitudinal direction of fingers. In addition, gate fingers of the both active regions are connected to a common gate bar arranged at the center, and a source bar and a drain bar are arranged symmetrically about this gate bar through the upper and lower unit transistor rows. Drain fingers and source fingers stride over the gate bar through an interlayer insulating film (see, for example, Japanese Patent Application Laid-Open No. 2002-299351, paragraphs [0019] and [0024], and FIG. 7).

As still another conventional high-frequency MESFET chip structure, there is known the following structure. A gate electrode pad is arranged in a central portion of a semiconductor chip, and connected to gate bus bars arranged on both sides of the gate electrode pad in parallel. A plurality of gate electrode fingers are led from the respective gate bus bars to the outside, and source electrode fingers and drain electrode fingers are alternately formed with the respective gate electrode fingers put therebetween. The drain electrode fingers are connected in parallel by drain electrode pads formed on both sides of the semiconductor chip. Source electrodes are shorted by a plurality of numbers by a source electrode pad formed thereon. This source electrode pad is formed to stride over the gate electrode fingers and the drain electrode fingers (see, for example, Japanese Patent Application Laid-Open No. 8-250671, paragraph [0008], and FIGS. 1 and 2).

In each of the conventional high-frequency MESFET's constituted as stated above, the unit transistors are arranged to form upper and lower groups in two rows. By so arranging, the size of the chip in the direction in which the unit transistors are arranged, i.e., the longitudinal direction of the chip is intended to be reduced, a length-to-breadth balance of the chip is intended to be improved, and signal uniformity is intended to be improved by arranging a plurality of gate pads at predetermined intervals.

Nevertheless, following a recent increase in the capacity of the high-frequency MESFET, demand for realizing higher power output, improving the high-frequency characteristic, and improving a thermal resistance characteristic of the device is rising.

### SUMMARY OF THE INVENTION

The present invention has been achieved to solve the conventional disadvantages. It is a first object of the present invention to provide a small-sized high-frequency semiconductor device high in power output, small in gain reduction, and excellent in high-speed performance.

According to one aspect of the invention, there is provided a high-frequency semiconductor device comprising: a substrate which includes an active region provided on a first main surface thereof; a first semiconductor element group which includes: a plurality of gate electrodes provided on a surface of the active region of the substrate, and aligned to one another to extend in a gate width direction; a plurality of first electrodes and second electrodes extending in parallel with the gate electrodes, ohmic-connected to the surface of the active region, and alternately provided through the gate electrodes; a second electrode connection wiring striding over each of the gate electrodes and each of first second electrodes and connecting each of the second electrodes, on first ends of the each gate electrode, the each first electrode, and the each second electrode, the first ends being on an equal side; and a first electrode connection wiring striding over the each gate electrode and the each second electrode and connecting the each first electrode, on second ends of the each gate electrode, the each first electrode, and the each second electrode; a second semiconductor element group equal in configuration to the first semiconductor element group, provided in an extension direction of the each gate electrode of the first semiconductor element group, and having the first electrode connection wiring provided to be proximate to the first electrode connection wiring of the first semiconductor element group; and a first gate electrode connection wiring, which is provided on the substrate between the first electrode connection wiring of the first semiconductor element group and the first electrode connection wiring of the second semiconductor element group, and to which the second end of the each gate electrode of each of the first and the second semiconductor element groups is connected.

Accordingly, in the high-frequency semiconductor device according to the present invention, the second electrode connection wiring, which connects each of the second electrodes, strides over each of the gate electrodes and each of the first electrodes on first ends of each gate electrode, each first electrode, and each second electrode of both the first and the second semiconductor element groups, the first ends being on an equal side. The first electrode connection wiring, which connects each first electrode, strides over each gate electrode and each second electrode on second ends of each gate electrode, each first electrode, and each second electrode. Therefore, a width of the second electrode connection wiring and that of the first electrode connection wiring can be made relatively large.

Hence, inductances of the second electrode connection wiring and the first electrode connection wiring can be reduced, and the gain of the high-frequency semiconductor device can be improved. In addition, the high-frequency characteristic and the high-speed performance of the high-frequency semiconductor device can be improved.

Other objects and advantages of the invention will become apparent from the detailed description given hereinafter. It should be understood, however, that the detailed description and specific embodiments are given by way of illustration only since various changes and modifications within the scope of the invention will become apparent to those skilled in the art from this detailed description.

### BRIEF DESCRIPTION OF THE DRAWINGS

FIG. 1 is a plan view which depicts a MESFET element according to one embodiment of the present invention.

FIG. 2 is a partially enlarged plan view of the MESFET element in a part A shown in FIG. 1.

FIG. 3 is a partially broken plan view of the MESFET element in a part B shown in FIG. 2.

FIG. 4 is a partially cross-sectional view of the MESFET element taken along a line VI-VI of FIG. 2.

FIG. 5 is a partially cross-sectional view of the MESFET element taken along a line V-V of FIG. 2.

FIG. 6 is a plan view which depicts a MESFET element according to a modification of one embodiment of the present invention.

FIG. 7 is a plan view which depicts a MESFET element according to one embodiment of the present invention.

FIG. 8 is a plan view which depicts a MESFET element according to a modification of one embodiment of the present invention.

In all figures, the substantially same elements are given the same reference numbers.

### DESCRIPTION OF THE PREFERRED EMBODIMENTS

### First Embodiment

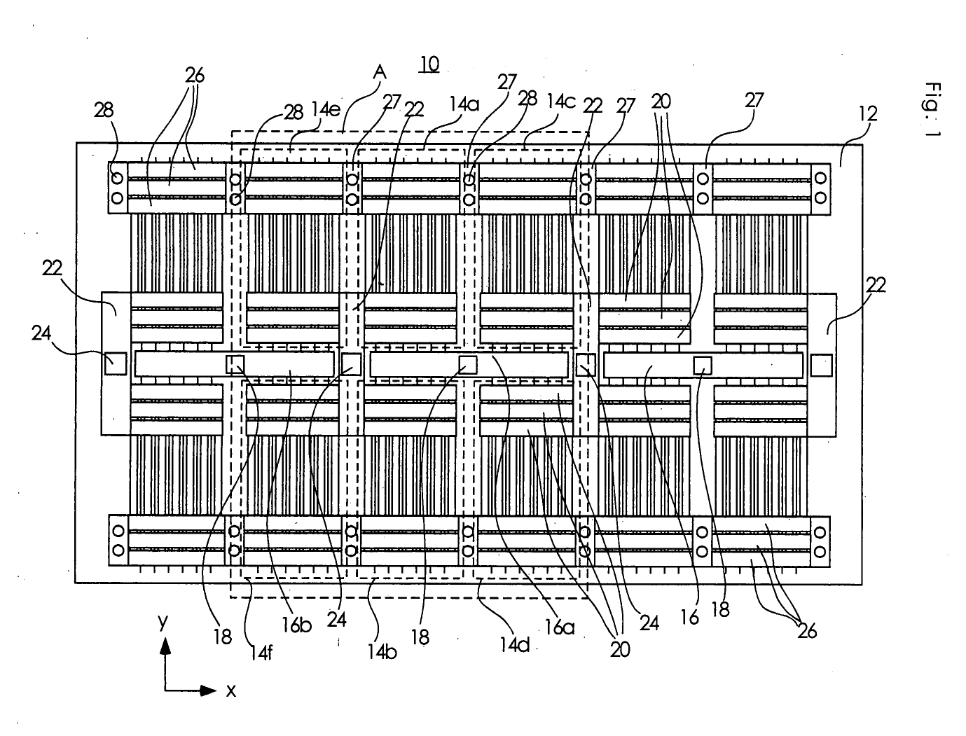

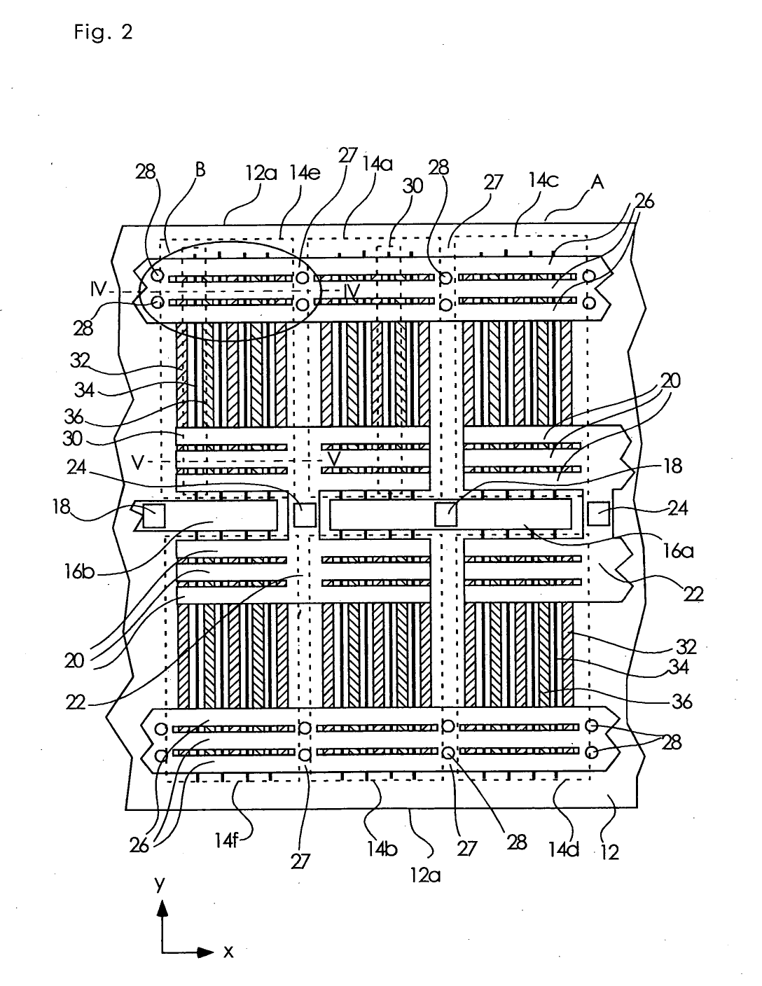

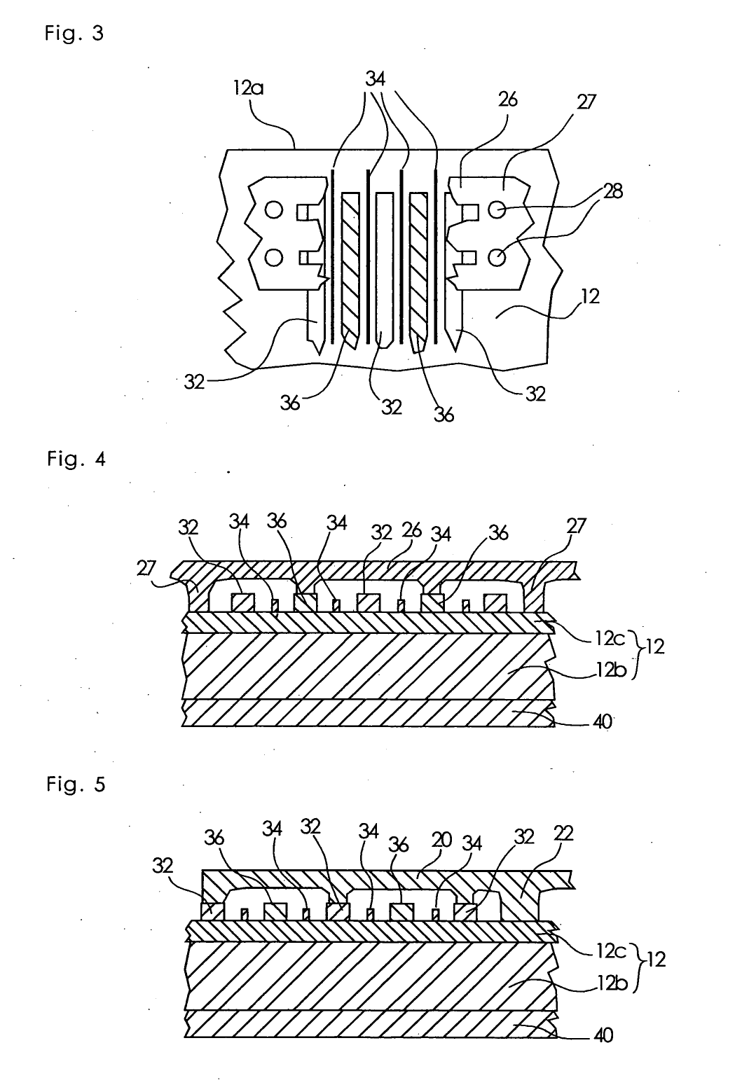

FIG. 1 is a plan view which depicts a MESFET element according to one embodiment of the present invention. FIG. 2 is a partially enlarged plan view of the MESFET element in a part A shown in FIG. 1. FIG. 3 is a partially broken plan view of the MESFET element in a part B shown in FIG. 2. FIG. 4 is a partially cross-sectional view of the MESFET element taken along a line VI-VI of FIG. 2. FIG. 5 is a partially cross-sectional view of the MESFET element taken along a line V-V of FIG. 2.

Referring to FIG. 1, the MESFET element 10 is constituted so that a plurality of, e.g., six unit MESFET groups 14a, 14b, 14c, . . . (hereinafter “cells”, which cells are often generically denoted by reference symbol 14), serving as semiconductor element groups each having a plurality of unit MESFET's arranged in parallel in an x-axis direction, are arranged on a semiconductor substrate 12 in the x-axis direction, and are arranged in a plurality of rows, e.g., two rows in a y-axis direction. The number of the cells 14 is determined according to a magnitude of a necessary output of a high-frequency semiconductor device.

The first cell 14a serving as a first semiconductor element group and the second cell 14b serving as a second semiconductor element group are aligned in they-axis direction which is an extension direction of gate electrodes of the first cell 14a. The third cell 14c serving as a third semiconductor element group and the fourth cell 14d serving as a fourth semiconductor element group are aligned in the y-axis direction which is an extension direction of gate electrodes of the third cell 14c. The third cell 14c and the fourth cell 14d are arranged adjacent to the first cell 14a and the second cell 14b at appropriate intervals in the x-axis direction, respectively.

A gate electrode bar 16 serving as a gate electrode connection wiring is provided between the two cells 14 adjacent to each other in the y-axis direction. Specifically, a gate electrode bar 16a serving as a first gate electrode connection wiring is provided between the first cell 14a and the second cell 14b and between the third cell 14c and the fourth cell 14d. The gate electrodes of the respective unit MESFET's in the first cell 14a, the second cell 14b, the third cell 14c, and the fourth cell 14d are connected to the gate electrode bar 16a.

A bonding pad 18 for connecting wires is arranged at the center of the gate electrode bar 16.

The fifth cell 14e serving as a fifth semiconductor element group and the sixth cell 14f serving as a sixth semiconductor element group are aligned in the y-axis direction which is the extension direction of gate electrodes on sides of the first cell 14a and the second cell 14b which sides are opposite to sides on which the third cell 14c and the fourth cell 14d are aligned. The fifth cell 14e and the sixth cell 14f are arranged at appropriate intervals from the first cell 14a and the second cell 14b, respectively. A gate electrode bar 16b serving as a second gate electrode connection wiring is provided between the fifth cell 14e and the sixth cell 14f. The gate electrodes of the respective unit MESFET's in the fifth cell 14e and the sixth cell 14f are connected to the gate electrode bar 16b. The gate electrodes of the unit MESFET's in two adjacent cells outside of the fifth cell 14e and the sixth cell 14f are also connected to the gate electrode bar 16b.

In each cell 14, a drain electrode connection wiring 20 serving as a first electrode connection wiring which strides over second electrodes, e.g., source electrodes and gate electrodes and which connects first electrodes, e.g., drain electrodes is provided on an end of the cell 14 on which each unit MESFET is proximate to the gate electrode bar 16, that is, on an inner end of the cell 14 serving as a second end thereof.

The drain electrode connection wirings 20 of the first cell 14a, the second cell 14b, the fifth cell 14e, and the sixth cell 14f are connected to a drain electrode lead wiring 22 provided to extend between the first cell 14a and the fifth cell 14e and between the second cell 14b and the sixth cell 14f and serving as a first electrode lead wiring. A bonding pad 24 for connecting wires is provided at the center of the drain electrode lead wiring 22.

In each cell 14, a source electrode connection wiring 26 serving as a second electrode connection wiring, which strides over the first electrodes, e.g., the drain electrodes and the gate electrodes, and which connects the second electrodes, e.g., the source electrodes, is provided on an end of the cell 14 on which each unit MESFET is outside relative to the gate electrode bar 16, i.e., an outer end of the cell 14 serving as a first end thereof. Each source electrode connection wiring 26 is connected to a source pad 27. The source pad 27 is connected to a plated heat sink (hereinafter “PHS”) provided on a rear surface of the semiconductor substrate 12 through via holes 28 and consisting of a metallic film, and grounded when sources are grounded.

Referring to FIG. 2, the cells 14 will be described.

In FIG. 2, each unit MESFET 30 is composed by a drain electrode 32, a gate electrode 34, and a source electrode 36. The drain electrode 32 or the source electrode 36 is shared between the unit MESFET 30 and the left or right adjacent unit MESFET 30. An interval of the gate electrodes 34 is, for example, about 20 μm.

In the cells 14 shown in FIG. 2, the number of unit MESFET's 30 in each cell is smaller than that shown in FIG. 1 for convenience's sake. In addition, in FIG. 2, the drain electrode 32 and the source electrode 36 are indicated by slant lines having different inclinations, respectively so as to facilitate distinguishing the drain electrode 32 from the source electrode 36. It is noted, however, that the slant lines do not indicate cross sections.

The number of unit MESFET's 30 included in one cell 14 is determined according to an allowable thermal resistance value. In one cell, a plurality of gate electrodes 34, e.g., about twelve gate electrodes 34 are provided, and twelve unit MESFET's 30 constitute one cell. When too many unit MESFET's 30 are included in one cell, the thermal resistance is increased, thereby hampering uniform operation of the respective cells, and deteriorating an output characteristic of the MESFET element 10.

In each unit MESFET 30, a gate width corresponds to a length of the gate electrode 34 in the y-axis direction, e.g., about 800 μm. In order to increase an output of the MESFET element 10, therefore, it is required to increase the length of the gate electrode 34 of each unit MESFET 30 in the y-axis direction as much as possible without reducing gain due to an increase in gate resistance, and to increase the number of unit MESFET's 30. It is also required so as not to increase a chip size.

According to the first embodiment, each cell 14 is constituted so that the unit MESFET's 30 each having the gate electrode 34 the length of which is increased so as not to cause a reduction in gain due to an increase in gate resistance, are aligned by the number determined according to the allowable thermal resistance value. By doing so, the output of the MESFET element 10 is increased while suppressing the increase in thermal resistance, and the cells 14 are arranged in two rows in the y-axis direction. In addition, one gate electrode bar 16a is arranged to extend in the x-axis direction between the four cells, e.g., between the cells 14a and 14b and between the cells 14c and 14d. The gate electrodes 34 of the cells 14a, 14b, 14c, and 14de are connected to the gate electrode bar 16a. By sharing one gate electrode bar 16a among the four cells 14, the length of the chip in the y-axis direction is reduced.

Furthermore, the source electrode connection wiring 26 serving as a so-called air bridge, which strides over the drain electrode 32 and the gate electrode 34 of each unit MESFET 30, and which connects the source electrode 36, is provided on the outer end of each cell 14 relative to the gate electrode bar 16, i.e., on a side near a chip side edge 12a on the substrate 12.

The drain electrode connection wiring 20 serving as a so-called air bridge, which strides over the source electrode 36 and the gate electrode 34 of each unit MESFET 30, and which connects the drain electrode 32 of each unit MESFET 30, is provided on the inner end of each cell 14 proximate to the gate electrode bar 16a, i.e., a central side of the substrate 12 proximate to the gate electrode bar 16a.

As shown in FIGS. 3 and 4, the source electrode connection wiring 26 has an air bridge structure, and strides over the drain electrodes 32 and the gate electrodes 34 through air gaps on the outer ends of the respective unit MESFET's 30. The source electrode connection wiring 26 is connected to the source electrodes 36 on their surfaces and connected to the surface of the substrate 12 through the source pad 27. In the first embodiment, the source electrode connection wiring 26 and the source pad 27 are formed integrally out of the Au plated layer using a well-known manufacturing method.

As shown in FIG. 5, the drain electrode connection wiring 20 has the same air bridge structure as that of the source electrode connection wiring 20, and strides over the source electrodes 36 and the gate electrodes 34 on inner ends of the respective unit MESFET's 30 through air gaps. The drain electrode connection wiring 26 is connected to the drain electrodes 32 on their surfaces and connected to the surface of the substrate 12 through the drain electrode lead wiring 22. In the first embodiment, the drain electrode connection wiring 20 and the drain electrode lead wiring 22 are formed integrally out of the Au plated layer using the well-known manufacturing method.

This air bridge structure is a structure including three divided connection wirings in parallel with one another so as to facilitate forming the air bridge structure while the width of the source electrode connection wiring 26 and that of the drain electrode connection wiring 20 in the y-axis direction are made sufficiently large. The width of each of the source electrode connection wiring 26 and the drain electrode connection wiring 20 in the y-axis direction is about 200 μm. That is, a sum of widths of the three divided connection wirings of the source electrode connection wiring 26 is about 200 μm. A sum of widths of the three divided connection wirings of the drain electrode connection wiring 20 is about 200 μm.

Accordingly, if the source electrode connection wiring 26 and the drain electrode connection wiring 20 have the air bridge structures formed on the unit MESFET's 30, respectively, it is possible to reduce the length of the chip in the y-axis direction and reduce an inductance of the source electrode connection wiring 26 and that of the drain electrode connection wiring 20. By reducing the inductances, the gain of the high-frequency MESFET element 10 can be improved. By improving the high-frequency characteristic of the high-frequency MESFET element 10, the high-speed performance thereof can be improved.

As shown in FIGS. 4 and 5, the semiconductor substrate 12 is composed by a semiconductor main body 12b consisting of GaAs, and an epitaxial layer 12c formed on a surface of the substrate main body 12b, serving as an operating region, and consisting of GaAs. A PHS 40 consisting of the Au plated layer is formed on the rear surface of the semiconductor substrate 12. The gate electrodes 34 are connected to the surface of the epitaxial layer 12c while currents carried across the gate electrodes 34 are rectified, and the drain electrodes 32 and the source electrodes 36 are ohmic connected.

The gate electrode bar 16 is formed by the Au plated layer using a well-known manufacturing method. In this embodiment, the operating region is formed by the GaAs epitaxial layer 12c. Alternatively, the operating region may be formed by injecting impurities into the GaAs substrate.

Referring to FIG. 2, the fifth cell 14e and the sixth cell 14f are arranged to be adjacent to the sides of the first cell 14a and the second cell 14b, respectively. The gate electrodes of the respective unit MESFET's in the fifth cell 14e and the sixth cell 14f are connected to the gate electrode bar 16b. The source electrode connection wirings 26 of the fifth cell 14e and the sixth cell 14f respective are connected to source electrode connection wirings 26 of the first cell 14a and the second cell 14b respective adjacent thereto through source pads 27. The drain electrode connection wiring 20 of the fifth cell 14e and the sixth cell 14f respective are connected to the drain electrode lead wiring 22 provided between the first cell 14a and the fifth cell 14e and between the second cell 14b and the sixth cell 14f.

As stated above, the gate electrode bar 16b is shared among the first cell group composed by, for example, the first cell 14a, the second cell 14b, the third cell 14c, and the fourth cell 14d. The drain electrode leadwiring 22 connected to the electrode connection wirings 20 of the second cell group composed by, for example, the first cell 14a, the second cell 14b, the fifth cell 14e, and the sixth cell 14f is shared among the second cell group. By doing so, the bonding pads 18 of the gate electrode bars 16 and the bonding pads 24 of the drain electrode lead wirings 22 can be alternately, uniformly arranged at the center of the chip in the chip longitudinal direction, that is, the x-axis direction, and uniform signal transmission can be realized.

Further, the bonding pads 18 and 24 are formed on the gate electrode bar 16 and the drain electrode lead wiring 22, respectively provided on the semiconductor substrate 12. As compared with the bonding pads formed on the air bridge structure, it is possible to prevent the respective unit MESFET's 30 from being mechanically damaged during wire bonding.

The MESFET element 10 according to the first embodiment is constituted so that the unit MESFET's 30 are distributed based on the cells each composed by a predetermined number of unit MESFET's 30. By suppressing an increase in thermal resistance, it is possible to increase the output of the MESFET element 10 and realize high power output thereof.

Furthermore, the bonding pads 18 on the gate electrode bars 16 and the bonding pads 24 on the drain electrode lead wirings 22 can be alternately, uniformly arranged at the center of the chip in the chip longitudinal direction, thereby making it possible to uniformly transmit signals.

Moreover, by arranging the gate electrode bars 16 at the center of the chip in the y-axis direction, each gate electrode bar 16 can be shared among the cells 14 arranged on the both sides of the gate electrode bar 16 across the gate electrode bar 16. In addition, by allowing the source electrode connection wirings 26 and the drain electrode connection wirings 20 to form the air bridge structures on the respective unit MESFET's 30, the length of the chip in the y-axis direction can be reduced, and the size of the MESFET element 10 can be reduced.

Additionally, since the source electrode connection wirings 26 and the drain electrode connection wirings 20 form the air bridge structures on the respective unit MESFET's 30, widths of the source electrode connection wirings 26 and the drain electrode connection wirings 20 in the y-axis direction can be made relatively large. Due to this, the inductances of the respective source electrode connection wirings 26 and the respective drain electrode connection wirings 20 can be reduced, the gain of the MESFET element 10 can be improved. The high-frequency characteristic and high-speed performance of the MESFET element 10 can be improved, accordingly.

By allowing the source electrode connection wirings 26 and the drain electrode connection wirings 20 to form the air bridge structures on the respective unit MESFET's 30, a capacitance of the MESFET element 10 can be reduced as compared with the MESFET element in which the source electrode connection wirings and the drain electrode connection wirings are provided through an insulating film. The high-speed performance of the MESFET element 10 can be thereby improved.

Consequently, the high-frequency semiconductor device high in power output, small in gain deterioration, and excellent in high-speed performance can be constituted.

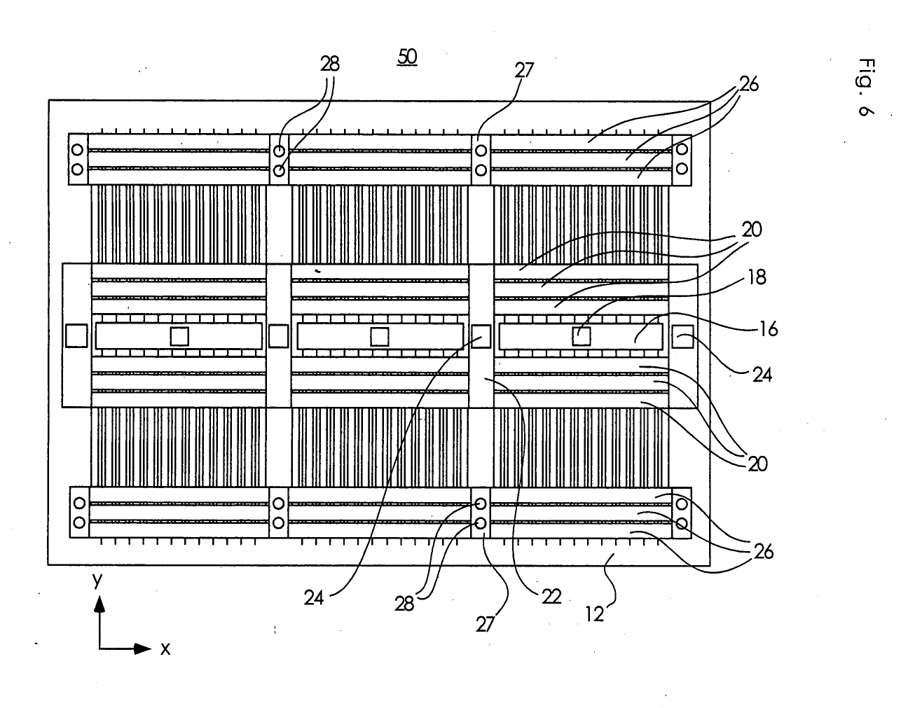

FIG. 6 is a plan view which depicts a MESFET element according to a modification of one embodiment of the present invention.

In FIG. 6, the same reference symbols as those shown in FIGS. 1 to 5 denote like or corresponding constituent elements. This shall apply hereafter.

Referring to FIG. 6, the MESFET element 50 differs from the MESFET element 10 in the following respects. In the cell group composed by the four cells, e.g., the first cell 14a, the second cell 14b, the third cell 14c, and the fourth cell 14d among which the gate electrode bar 16 is shared, the source pads 27 formed between the first cell 14a and the third cell 14c and between the second cell 14b and the fourth cell 14d are eliminated, thereby eliminating gaps formed there between, and arranging the adjacent unit MESFET's 30 to be alternately connected. The other constitution is the same as that of the MESFET element 10.

By thus constituting the MESFET element 50, the longitudinal direction of the chip, that is, the length of the chip in the x-axis direction can be further reduced.

### Second Embodiment

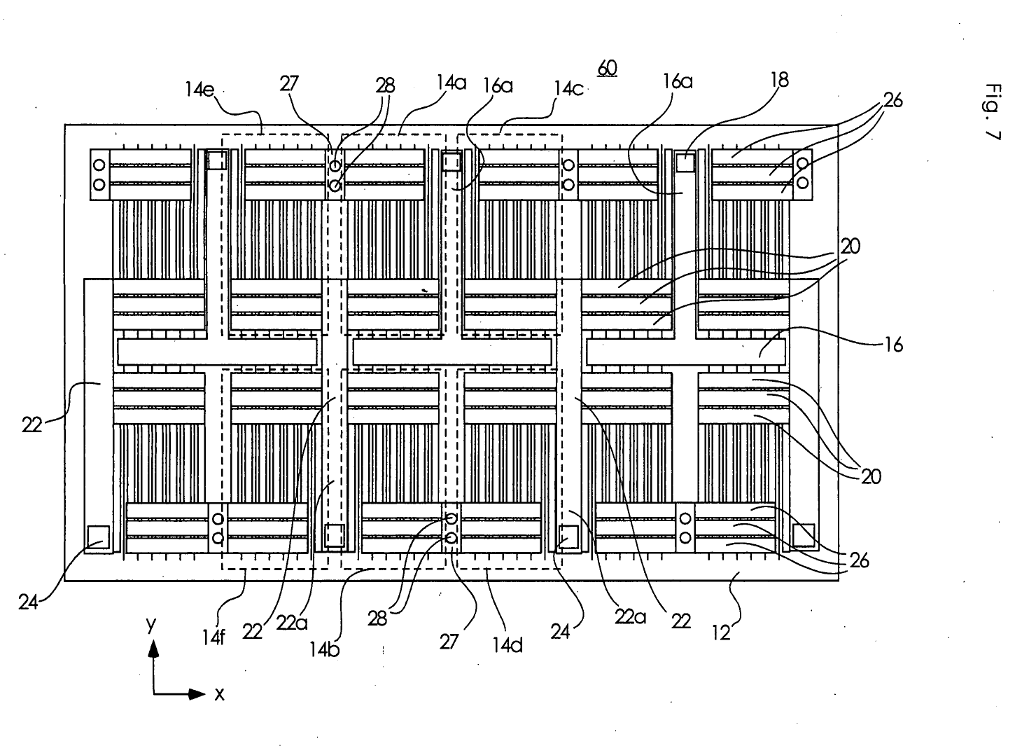

FIG. 7 is a plan view which depicts a MESFET element according to one embodiment of the present invention.

Referring to FIG. 7, the MESFET element 60 is constituted as follows. In a cell group composed by four cells, e.g., the first cell 14a, the second cell 14b, the third cell 14c, and the fourth cell 14d among which the gate electrode bar 16a is shared, the source pad 27 for connecting the source electrode connection wiring 26 of the first cell 14a to that of the third cell 14c is eliminated. The gate electrode bar 16a is arranged to extend up to outer ends of the first cell 14a and the third cell 14c in the y-axis direction along the sides of the first cell 14a and the third cell 14c between the first cell 14a and the third cell 14c. The gate electrode bar 16, which has an extension, formed into an inverse T shape, in FIG. 7, is provided, and the bonding pad 18 is formed on an outer end of the extension.

Furthermore, in a cell group composed by four cells, e.g., the first cell 14a, the second cell 14b, the fifth cell 14e, and the sixth cell 14f among which the drain electrode lead wiring 22 is shared, the source pad 27 for connecting the source electrode connection wiring 26 of the second cell 14b to that of the sixth cell 14f is eliminated. The drain electrode lead wiring 22 is arranged to extend up to outer ends of the second cell 14b and the sixth cell 14f in they-axis direction opposite to the direction in which the gate electrode bar 16a extends along the sides of the second cell 14b and the sixth cell 14f, thereby providing an extension 22a of the drain electrode lead wiring 22. In addition, the bonding pad 24 is provided on an outer end of this extension 22a.

Namely, in the MESFET element 10 according to the first embodiment, the bonding pads 18 of the gate electrode bar 16a and the bonding pads 24 of the drain electrode lead wirings 22 are alternately provided on a line at the center of the chip. In the MESFET element 60 according to the second embodiment, by contrast, the bonding pads 18 of the gate electrode bar 16a are provided on one chip side edge located in an opposite direction to the x-axis at the center of the chip, and the bonding pads 24 of the drain electrode lead wiring 22 are provided on the other chip side edge.

As can be seen, the MESFET element 60 thus constituted can exhibit not only the same advantages as those of the MESFET element 10 according to the first embodiment but also shorten bonding wires for bonding the device 60 to an input matching circuit or an output matching circuit provided on the substrate 12 in one package. Therefore, a high-frequency semiconductor device with a reduced inductance, a reduced fluctuation in impedance matching, and uniform electric characteristic can be constituted, and yield can be improved. Hence, the high-frequency semiconductor device excellent in electric characteristics and low in cost can be obtained.

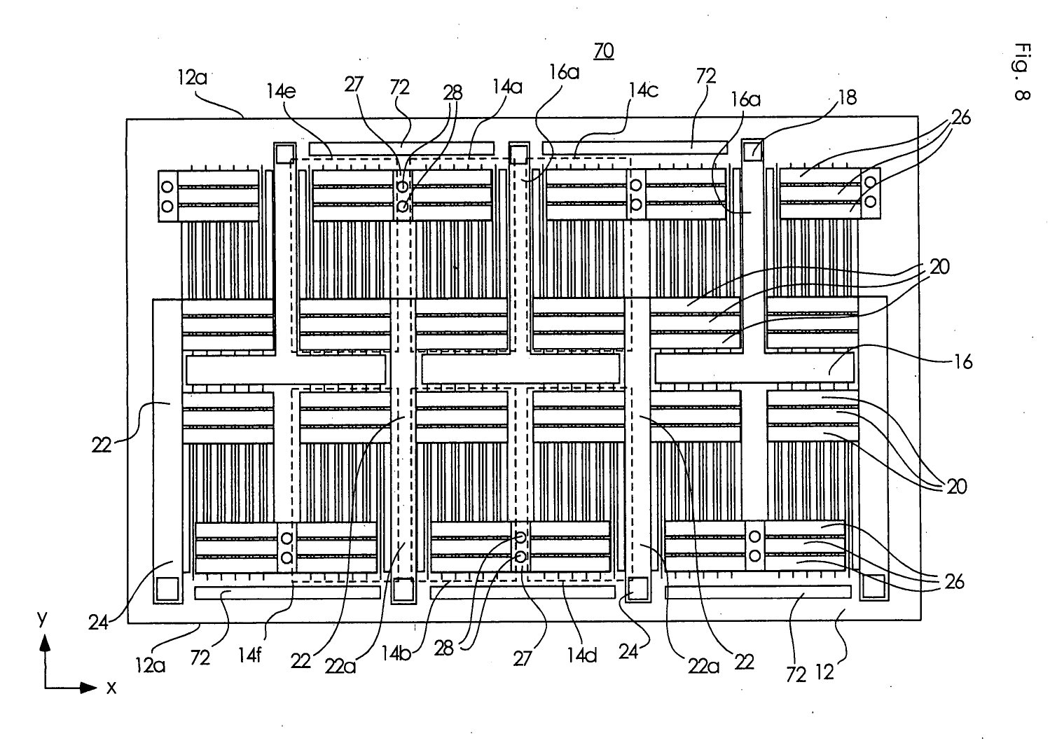

FIG. 8 is a plan view which depicts a MESFET element according to a modification of one embodiment of the present invention.

Referring to FIG. 8, the MESFET element 70 differs from the MESFET element 60 in the following respects. The extension of the gate electrode bar 16a along sides of the cells 14 provided on both sides of the gate electrode bar 16a, e.g., the first cell 14a and the third cell 14c, is arranged to extend beyond the outer ends of these cells 14 so as to be close to a chip side edge 12a. The extension 22a of the drain electrode lead wiring 22 is arranged to extend beyond the outer ends of the cells 14 provided on the both sides of the drain electrode lead wiring 22, e.g., the second cell 14b and the sixth cell 14f, so as to be close to the chip side edge 12a. In addition, aoscillation suppression circuit 72 and an electrode connection wiring having a resistance, for example, are arranged between the extensions of the adjacent gate electrode bars 16 and between the extension 22a of the adjacent drain electrode lead wirings 22, thereby connecting the bonding pad 18 of the gate electrode bar 16 to the bonding pad 24 of the drain electrode lead wiring 22.

By so constituting, the oscillation between the cells 14 can be suppressed.

In the embodiments stated so far, the drain electrode connection wirings 20 are provided to be proximate to the gate electrode bars 16, and the source electrode connection wirings 26 are provided on the outer chip side edge relative to the gate electrode bars 16. Conversely, even if the source electrode connection wirings 26 are provided to be proximate to the gate electrode bars 16 and the drain electrode connection wirings 20 are provided on the outer chip side edge relative to the gate electrode bars 16, the same advantages can be exhibited. The respective embodiments have been described taking the MESFET element as an example. However, even if the other high-frequency FET, e.g., a high electron mobility transistor (HEMT), a heterostructure field-effect transistor (HFET), or a metal oxide semiconductor field-effect transistor (MOSFET) is used, the same advantages can be exhibited.

As can be understood, the high-frequency semiconductor device according to the present invention is suited to be used as a high-frequency semiconductor device such as a high power amplifier employed in the communication apparatus such as a transmitter receiver for satellite communication or mobile communication. While the presently preferred embodiments of the present invention have been shown and described. It is to be understood these disclosures are for the purpose of illustration and that various changes and modifications may be made without departing from the scope of the invention as set forth in the appended claims.

1. A high-frequency semiconductor device comprising:
a substrate which includes an active region located on a first main surface of the substrate;
a first semiconductor element group which includes:
a plurality of gate electrodes on a surface of the active region of the substrate, aligned with one another and extending in a gate width direction;
a plurality of first electrodes and a plurality of second electrodes extending parallel to the gate electrodes, ohmic-connected to the surface of the active region, and alternately located relative to the gate electrodes;
a second electrode connection wiring striding over each of the gate electrodes and each of the first electrodes and connected to each of the second electrodes, located at first ends of each gate electrode, each first electrode, and each second electrode, the first ends being at one side of the first semiconductor element group; and
a first electrode connection wiring striding over each of the gate electrodes and each of the second electrodes and connected to each first electrode, located at second ends of each gate electrode, each first electrode, and each second electrode;
a second semiconductor element group having the same configuration as the first semiconductor element group, located along a direction of extension of each gate electrode of the first semiconductor element group, and having the first electrode connection wiring located proximate to the first electrode connection wiring of the first semiconductor element group; and
a first gate electrode connection wiring, located on the substrate between the first electrode connection wiring of the first semiconductor element group and the first electrode connection wiring of the second semiconductor element group, and to which the second end of each gate electrode of each of the first and second semiconductor element groups is connected.

2. The high-frequency semiconductor device according to claim 1, further comprising a first electrode lead wiring on the subtrate at a side of each of the first and second semiconductor element groups, wherein the first electrode connection wirings of the first and second semiconductor element groups are connected to the first electrode lead wiring.
electrode connection wirings of the first and second semiconductor element groups are connected to the first electrode lead wiring.

3. The high-frequency semiconductor device according to claim 2, further comprising:
a third semiconductor element group having the same configurations as the first semiconductor element group; and
a fourth semiconductor element group having the same configuration as the first semiconductor element group, located along a direction of extension of each gate electrode of the third semiconductor element group, and having the first electrode connection wiring located proximate to the first electrode connection wiring of the third semiconductor element group, wherein
the first semiconductor element group and the third semiconductor element group are aligned with each other,
the second semiconductor element group and the fourth semiconductor element group are aligned with each other,
the first gate electrode connection wiring extends between the first electrode connection wiring of the third semiconductor element group and the first electrode connection wiring of the fourth semiconductor element group, and
the second end of each gate electrode of each of the third and fourth semiconductor element groups is connected to the first gate electrode connection wiring.

4. The high-frequency semiconductor device according to claim 3, further comprising:
a fifth semiconductor element group having to same configurations as the first semiconductor element group;
a sixth semiconductor element group having the same configuration as the first semiconductor element group, located along a direction of extension of each gate electrode of the fifth semiconductor element group, and having the first electrode connection wiring located proximate to the first electrode connection wiring of the fifth semiconductor element group; and
a second gate electrode connection wiring, located on the substrate between the first electrode connection wiring of the fifth semiconductor element group and the first electrode connection wiring of the sixth semiconductor element group, and to which the second end of each gate electrode of each of the fifth and sixth semiconductor element groups is connected, wherein
the fifth semiconductor element group is aligned with the third semiconductor element group, with the first semiconductor element group between the third and fourth semiconductor element groups,
the sixth semiconductor element group is aligned to with the fourth semiconductor element group, with the second semiconductor element group between the fourth and sixth semiconductor element groups, and
the first electrode connection wiring of each of the fifth and sixth semiconductor element groups is connected to the first electrode lead wiring.

5. The high-frequency semiconductor device according to claim 1, including
a gate electrode connection wiring arranged on the substrate on a side of the first semiconductor element group, extending parallel to the direction of extension of the gate electrode, an end of the gate electrode connection wiring being located proximate to the first end of each of the first electrodes of the first semiconductor element group, and
the first electrode lead wiring arranged on the substrate on a side of the second semiconductor element group, extending parallel to the direction of extension of the gate electrode, one end of the first electrode lead wiring being located proximate to the first end of each of the first electrodes of the second semiconductor element group.
